(19) United States
(12) Patent Application Publication
(10) Pub. No.: US 2008/0116767 A1
(43) Pub. Date: May 22, 2008

(54) Piezoelectric generation system and generation method thereof

(76) Inventors: Shan-Yi Yu, Jhonghe City (TW); Wen-Yu Tsai, Jhonghe City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/600,026

(22) Filed: Nov. 16, 2006

(51) Int. Cl. H01L 41/08

(52) U.S. Cl. 310/339

(57) ABSTRACT

A piezoelectric generation system and piezoelectric generating method for use in a nebulizer are disclosed. The system and method comprises using a processing unit to control the frequency generation unit to continuously generate the first electrical signals with a serial predetermined frequency band range (or third electrical signals after converting the first electrical signals) to be transmitted to a piezoelectric generating element. The piezoelectric generating element then generates a series of corresponding second electrical signals (or the fourth electrical signals after converting the second electrical signals) to be transmitted to the processing unit based on the first electrical signals or the third electrical signals. The processing unit controls the frequency generation unit to provide the first electrical signals (or the third electrical signals) with an optimum frequency to be transmitted to the piezoelectric generating element based on the frequency of the first electrical signals and the voltage value (or the feedback frequency value) corresponding to second electrical signals (or the third electrical signals).

### FIELD OF THE INVENTION

The present invention generally relates to a piezoelectric generation system and generation method thereof for use in a nebulizer, and more specifically relates to the technical field that uses the sweep frequency and electrical signal feedback.

### BACKGROUND OF THE INVENTION

Referring to FIG. 1 for the block diagram of a conventional piezoelectric generation system is illustrated. The piezoelectric generation system 1 comprises a processor 10, a frequency generator 11, a signal amplifier 12 and a piezoelectric generating element 13. The processor 10 generates a predetermined control signal 101 to be transmitted to the frequency generator 11. The frequency generator 11 then generates a first electrical signal 111 with a predetermined frequency to be transmitted to the signal amplifier 12. Lastly, after the first electrical signal 111 is processed by the signal amplifier 12, the signal 121 is amplified. The piezoelectric generating element 13 is driven by the signal 121 so that the nebulizer can work normally.

However, the characteristics of every piezoelectric generating element 13 applied to the nebulizers have some differences. The predetermined control signal 101 or the predetermined frequency or the first electrical signal 111 needs to be predetermined before the nebulizers become available in the market. Alternatively, the piezoelectric generating element needs to be replaced or adjusted due to deterioration. The piezoelectric generating element 13 of the nebulier can be ensured to work at the optimum frequency.

The adjustment at real-time may not be achieved in the prior art. Moreover, an appropriate protection alarm or a protection action is not provided when the nebulizer is in malfunction. Therefore, the inventor of the present invention based on years of experience in the related field to conduct extensive researches and experiments, and finally invented a piezoelectric generation system and piezoelectric generating method thereof for use in the nebulzier as a method or a basis for overcoming the aforementioned problems.

### SUMMARY OF THE INVENTION

Briefly, a primary object of the present invention is to provide a piezoelectric generation system and piezoelectric generating method thereof applied to a nebulizer, thereby automatically providing optimum working frequencies for a piezoelectric generating element of the nebulizer.

To achieve the foregoing object, the piezoelectric generation system comprises a frequency generation unit, a piezoelectric generating element and a processing unit, or further comprises a signal amplifier unit or a feedback signal receiving unit. The processing unit can control the frequency generation unit. Alternatively, first electrical signals with a serial predetermined frequency band range are autonomously generated by frequency generation unit through the predetermined setting of the outside so that the first electrical signals then are transmitted to the piezoelectric generating element (Alternatively the first electrical signals are converted by the signal simplifier unit into third electrical signals to be transmitted to the piezoelectric generating element). The piezoelectric generating element then generates a series of corresponding second electrical signals for the processing unit based on the first electrical signals (or third electrical signals) (Alternatively, the second electrical signals are converted by the feedback signal receiving unit into fourth electrical signals for the processing unit). Afterward the processing unit controls the frequency generation unit to provide the first electrical signals with an optimum frequency to the piezoelectric generating element based on the voltage value (or the feedback frequency value) of the second electrical signals (or the fourth electrical signals) and the frequency value corresponding to the first electrical signals (Alternatively, the first electrical signals are converted by the signal amplifier unit into the third electrical signals to be transmitted to the piezoelectric generating element).

Moreover, a second object of the present invention is to provide a piezoelectric generation system and piezoelectric generating method thereof applied to a nebulizer to detect the working situation of the piezoelectric generating element within the nebulizer, and provides a protection alarm or a protection action.

In accordance with the object of the present invention, the piezoelectric generation system comprises a frequency generation unit, a piezoelectric generating element, a processing unit and a protection unit, or further comprises a signal amplifier unit or a feedback signal receiving unit. The processor obtains the voltage value (or the feedback frequency value) with a better frequency based on a predetermined frequency and voltage (or feedback frequency) relation table. It should be noted that the relation table is predetermined by designers or obtained through the processing unit pre-executing a sweep function. Afterward, the processing unit then sends a control signal to the frequency generation unit. The frequency generation unit sends the first electrical signals with a better frequency to the piezoelectric generating element by receiving the control signal (Alternatively, the first electrical signals are converted by the signal amplifier unit into the third electrical signals to be transmitted to the piezoelectric generating element). The piezoelectric generating element continuously generates corresponding second electrical signals to be transmitted to the processing unit based on the first electrical signals (or the third electrical signals) (Alternatively, the second electrical signals are converted by the feedback signal receiving unit into the fourth electrical signals to be transmitted to the processing unit). Lastly, the processing unit periodically or non-periodically or continuously detects whether or not the voltage value (or the feedback frequency value) of the second electrical signals (or the fourth electrical signals) has any anomalous variation based on the second electrical signals (or the fourth electrical signals). If any anomalous variation occurs, the processing unit then notifies the protection unit to activate a protection alarm or a protection action. The protection alarm or the protection action includes a display alarm or a buzzer alarm, or is to turn off the power of the nebulizer or a lighting alarm.

Furthermore, a piezoelectric generating method is further disclosed according to the piezoelectric generation system, and the method comprises the following steps:
(a) The processing unit controls the frequency generation unit to continuously generate the first electrical signals with a serial predetermined frequency band for the piezoelectric generating element. Alternatively, the first electrical signals are converted by the signal amplifier unit into the third electrical signals to be transmitted to the piezoelectric generating element. It should be noted that the frequency generation unit can continuously and autonomously generate the first electrical signals with the serial predetermined frequency band range through the predetermined setting of the outside.
(b) The piezoelectric generating element then generates a series of corresponding second electrical signals to be transmitted to the processing unit based on the first electrical signals (or the third electrical signals). Alternatively, the second electrical signals are converted by the feedback signal receiving unit into the fourth electrical signals to be transmitted to the processing unit.
(c) The processing unit then obtains the voltage value (or the feedback frequency value) of the second electrical signals (or the fourth electrical signals) and the frequency relation corresponding to the first electrical signals by receiving the second electrical signals (or the fourth electrical signals) from the feedback signal receiving unit.
(d) The processing unit then generates a specific control signal to control the frequency generation unit to provide the first electrical signals with a better frequency to be transmitted to the piezoelectric generating element based on the aforesaid voltage (or the feedback frequency) and the frequency relation. Alternatively, the first electrical signals are converted by the signal amplifier into the third electrical signals to be transmitted to the piezoelectric generating element for performing the optimum work.
(e) When the frequency generation unit receives the control signal and the first electrical signals with a better frequency is sent to the piezoelectric generating element (Alternatively, the first electrical signals are converted by the signal amplifier into the third electrical signals to be transmitted to the piezoelectric generating element), the piezoelectric generating element then generates second electrical signals correspond to the first electrical signals. Alternatively, the second electrical signals are converted by the feedback signal receiving unit into the fourth electrical signals to be transmitted to the processing unit.
(f) The processing unit periodically or non-periodically or continuously detects the variation of the voltage value (or the feedback frequency value) of the second electrical signals (or the fourth electrical signals).
(g) If the voltage value (or the feedback frequency value) detected by the processing unit has anomalous variation, the processing unit then notifies the protection unit to generate protection alarm or a protection action, including a display alarm or a buzzer alarm, or the power of the nebulzier to be turned off or a lighting alarm.

To make it easier for our examiner to understand the object of the invention, its innovative features and performance, a detailed description and technical characteristics of the present invention are described together with the drawings as follows.

### BRIEF DESCRIPTION OF THE DRAWINGS

FIG. 1 is a block diagram of a conventional piezoelectric generation system;

FIG. 2 is a block diagram of a piezoelectric generation system of the invention;

FIG. 3 is a schematic relation diagram of voltages and (or feedback frequencies) frequencies of a piezoelectric generation system of the invention;

FIG. 4 is another schematic relation diagram of voltages and (or feedback frequencies) frequencies of a piezoelectric generation system of the invention;

FIG. 5 is a flowchart of a piezoelectric generating method of the invention;

FIG. 6 is another block diagram of a piezoelectric generation system of the invention; and

FIG. 7 is another flowchart of a piezoelectric generating method of the invention.

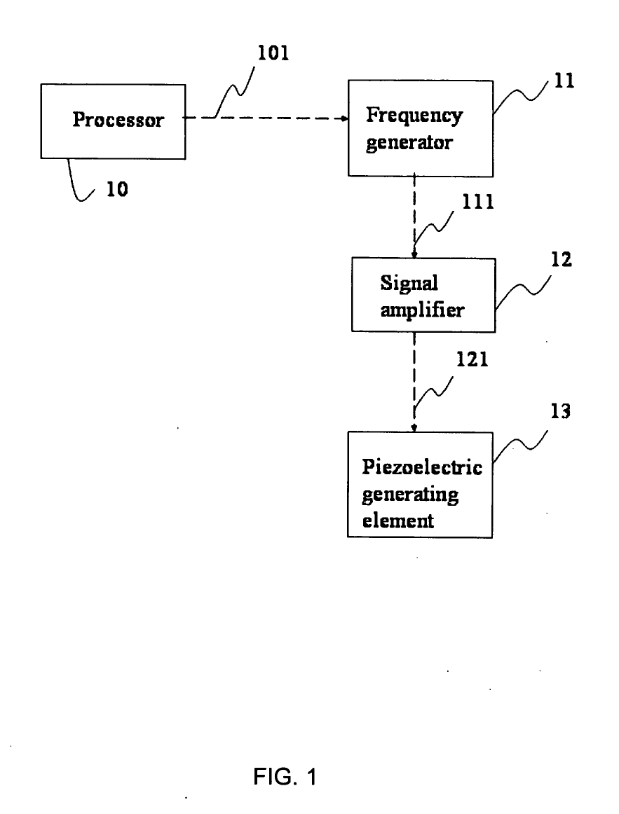

### DETAILED DESCRIPTION OF THE PREFERRED EMBODIMENTS

Referring to the related figures for the piezoelectric generation system and piezoelectric generating method thereof for use in a medical nebulizer according to a preferred embodiment of the present invention, wherein the same elements are described by the same reference numerals.

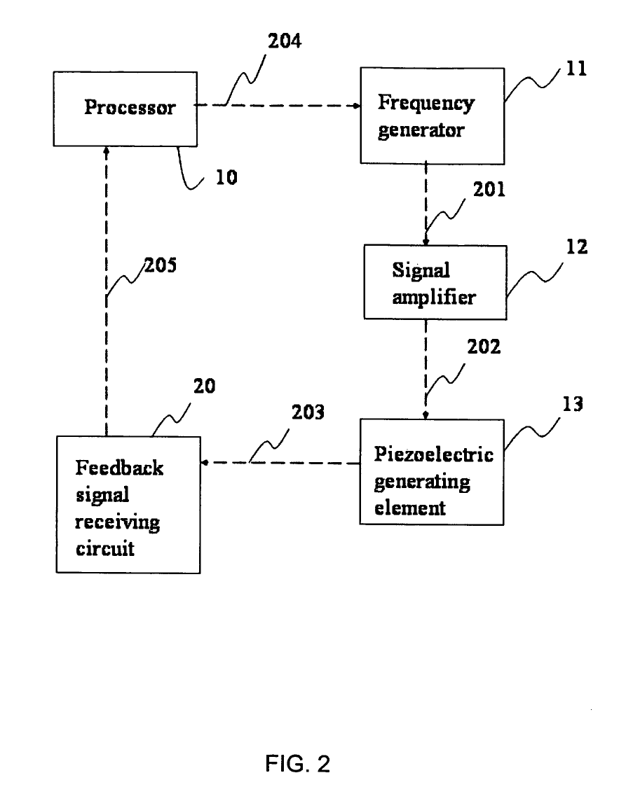

Referring to FIG. 2 for the block diagram of a piezoelectric generation system used in a nebulizer of the invention is illustrated. The piezoelectric generation system 2 comprises a processor 10, a frequency generator 11, a signal amplifier 12, a piezoelectric generating element 13 and a feedback signal receiving circuit 20. The frequency generator 11 can send first electrical signals 201 with different frequency range (e.g., 90-100 Kilohertz) to the piezoelectric generating element 13, or send third electrical signals 202 with different frequency range (e.g., 90-100 kHz) via the signal amplifier 12 to the piezoelectric generating element 13. The piezoelectric generating element 13 usually needs to receive the first electrical signal 201 or the third electrical signal 202 with a specific frequency (also called a working frequency), thereby working normally. In the invention, when the nubulizer is started, the processor 10 would implement a sweep frequency function. In another word, the processor 10 uses a series of control signals 204 to control the first electrical signal 201 with different frequencies provided by the frequency generator 11. After the first electrical signal is converted by the signal amplifier 13 into the third electrical signal 201 that then is transmitted to the piezoelectric generating element 13. Meanwhile, the piezoelectric generating element 13 can provide a second electrical signal 203 to the feedback signal receiving circuit 20. Rectification or filtering is implemented for the second electrical signal 201 through the feedback signal receiving circuit 20. Alternatively, a fourth electrical signal 205 is generated to be transmitted to the processor 10 after combining both rectification and filtering. The processor then calculates voltage values (or feedback frequency values) replied by the piezoelectric generating element 13 at the different frequency range based on the first electrical signals 201 and the fourth electrical signals 205. It should be noted that the frequency generator 11 can control generation of the first electrical signal 201 with a series of frequencies through the processor 10. Alternatively, the first electrical signals 201 with a series of frequencies are autonomously generated by the predetermined setting of the outside.

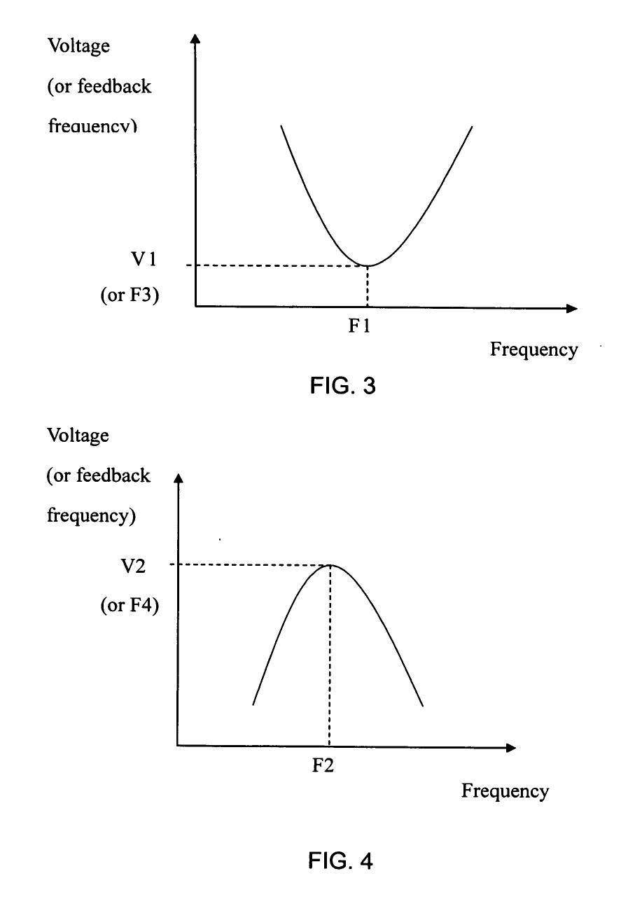

Referring to FIG. 3 for the schematic relation diagram of voltage values (or feedback frequency values) replied by the piezoelectric generating element 13 at the different frequency range is illustrated. The transverse axis shows different frequency values given to the piezoelectric generating element 13, and the vertical axis shows voltage values (or feedback frequency values) replied by the piezoelectric generating element 13 corresponding to the frequency values. In the embodiment, when the frequency generator 11 gives the frequency range for the piezoelectric generating element 13, the processor 10 usually samples the frequency value of 2 to the power of n (n is an integer number) to calculate and obtain the voltage value (or the feedback frequency value) corresponding to 2 to the power of n. The processor 10 usually obtains the frequency value (symbol F1 shown in figure) corresponding to the minimum voltage value (symbol V1 shown in figure) (or the feedback frequency value as symbol F3 shown in figure) to be an optimum working frequency of the piezoelectric generating element 13.

Corresponding to FIG. 3, referring to FIG. 4 for another relation diagram of voltage values (or feedback frequency values) replied by the piezoelectric generating element 13 at the different frequency range is illustrated. The transverse axis shows different frequency values given to the piezoelectric generating element 13, and the vertical axis shows voltage values (or feedback frequency values) replied by the piezoelectric generating element 13 corresponding to the frequency values. In the embodiment, when the frequency generator 11 gives the frequency range for the piezoelectric generating element 13, the processor 10 usually samples the frequency value of 2 to the power of n (n is an integer number), and obtains the voltage value (or the feedback frequency value) corresponding to 2 to the power of n. The processor 10 would obtain the frequency value (symbol F2 shown in figure) corresponding to the maximum voltage value (symbol V2 shown in figure) (or the feedback frequency value as symbol F4 shown in figure) to be an optimum working frequency of the piezoelectric generating element 13.

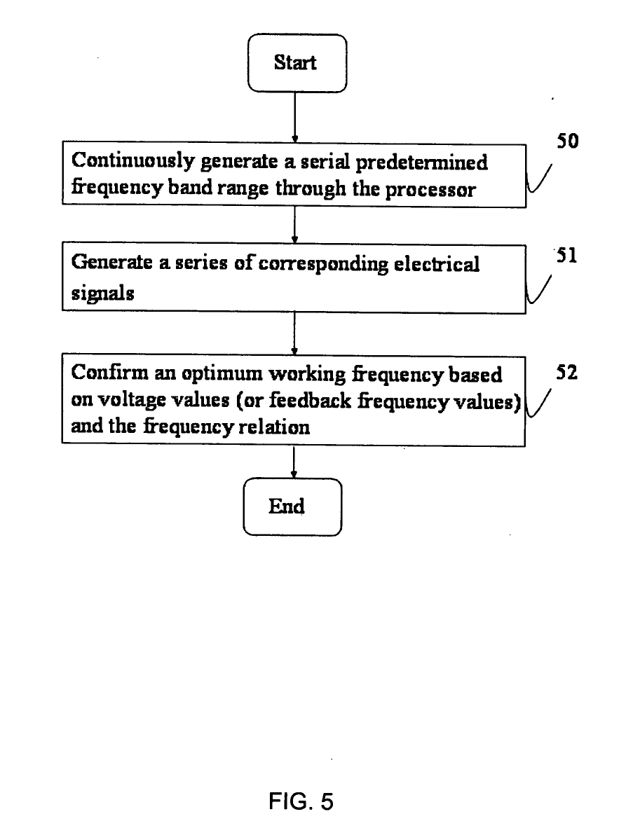

Referring to FIG. 5 for the flowchart of a piezoelectric generating method applied to a nebulizer of the invention is illustrated. Corresponding to FIG. 2 and FIG. 3 or FIG. 4, the method includes the following steps:

Step 50: Controlling the frequency generator 11 to continuously generate first electrical signals with a serial predetermined frequency band range (e.g., 90-100 kHz) through the processor 11, and converting the first electrical signal into the third electrical signal 202 to be transmitted to a piezoelectric generating element through the signal amplifier 12. It should be noted that the frequency generator 11 also autonomously generates the first electrical signals 201 with the serial predetermined frequency range (e.g., 90-100 kHz) that are converted by the signal amplifier 12 into the third electrical signals 202 to be transmitted to a piezoelectric generating element.

Step 51: Enabling the piezoelectric generating element 13 to generate a series of corresponding second electrical signals 203 based on the third electrical signals 202, and converting the second electrical signals into the fourth electrical signals 205 to be transmitted to the processor 10 through the feedback signal receiving circuit 20.

Step 52: Enabling the processor 10 to confirm and control the frequency generator 11 to provide an optimum working frequency for the piezoelectric generating element 13 based on voltage values (or feedback frequency values) of the fourth electrical signals 205 and the corresponding frequency relation (as shown in FIG. 3 or FIG. 4) (usually obtaining the working frequency F1 corresponding to the minimum voltage value VI or the minimum feedback frequency value F3 as shown in FIG. 3, or obtaining the working frequency F2 corresponding to the maximum voltage value V2 or the maximum feedback frequency value F4 as shown in FIG. 4).

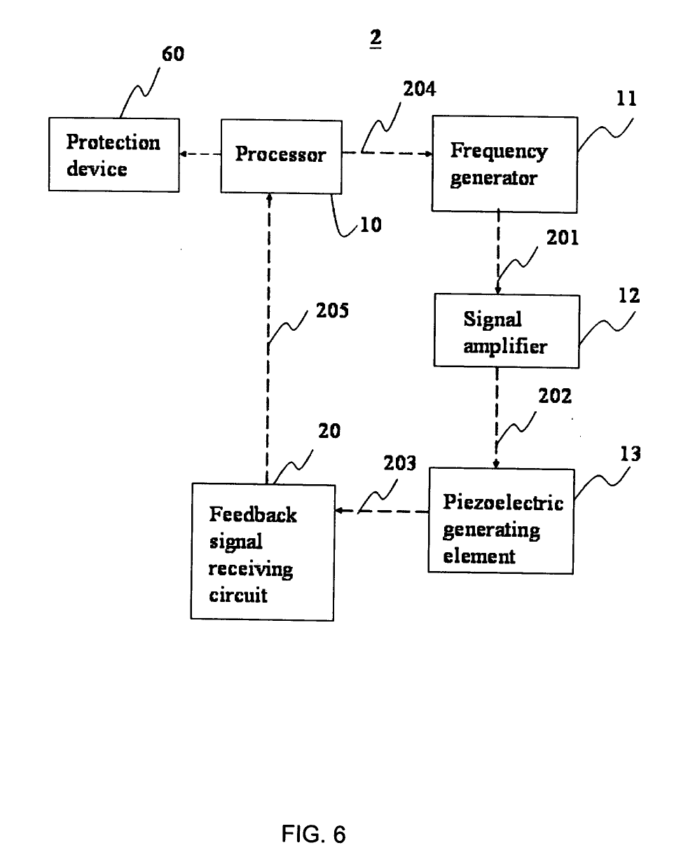

Referring to FIG. 6 for another block diagram of a piezoelectric generation system applied to a nebulizer of the invention is illustrated. After the processor 10 executes a sweep frequency to confirm the frequency generator 11 to generate the first electrical signals 201 with which frequencies and the third electrical signals 202 are converted by the signal amplifier 12 to the piezoelectric generating element 13, the piezoelectric generating element 13 is ensured to work under the optimum working frequency. However, to ensure the piezoelectric generating element to work under the optimum working frequency or when the nebulizer is in malfunction or needs to be replaced with the piezoelectric generating element 13, an appropriate protection alarm or a protection action must provide. The processor 10 then detects whether or not the fourth electrical signals 205 fed by the piezoelectric generating element has any anomalous variation through the feedback signal receiving circuit 20. For example, if the difference between the fourth electrical signals 205 detected by the processor 10 and the previous detected fourth electrical signals 205 achieves a predetermined threshold, the processor 10 then notifies a protection device 60 to perform a protection alarm or a protection action, including a display alarm or a buzzer alarm or the power of the nebulizer to be turned off or a lighting alarm.

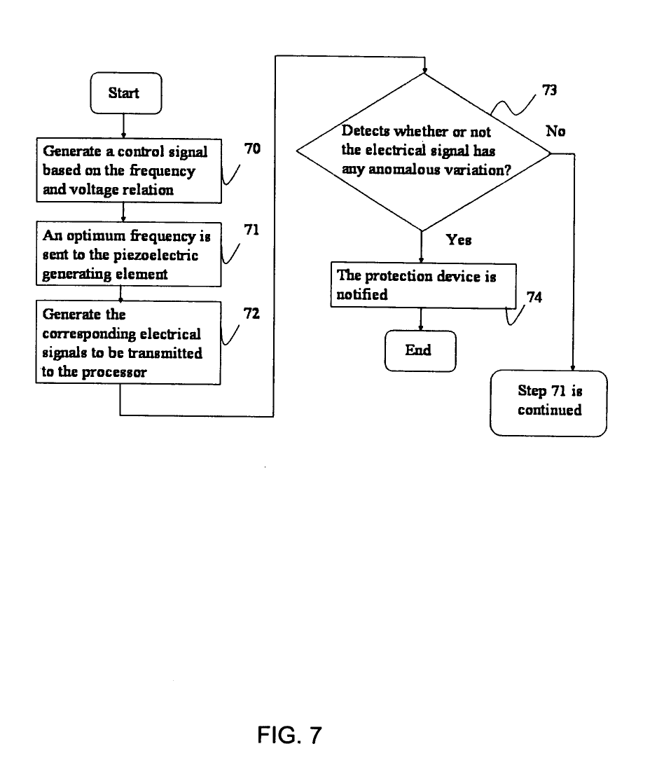

Referring to FIG. 7 for another flowchart of a piezoelectric generating method applied to a nebulizer of the invention is illustrated. Corresponding to FIG. 6 and FIG. 3 or FIG. 4, the method includes the following steps:

Step 70: The processing unit generates a control signal 204 based on the frequency and voltage relation table as shown in FIG. 3 or FIG. 4.

Step 71: The first electrical signals 201 with an optimum frequency is sent to the piezoelectric generating element 13 through the frequency generator 10 receiving the control signal 204 from the processor 10. Alternatively, the third electrical signal 202 with an optimum frequency is transmitted tot he piezoelectric generating element 13 through the signal amplifier 12.

Step 72: The piezoelectric generating element 13 generates the second electrical signals 203 to be transmitted to the processor 10. Alternatively, the fourth electrical signals 205 are generated by the feedback signal receiving circuit 20 to the processor 10.

Step 73: The processor 10 continuously detects whether or not the second electrical signal 203 or the fourth electrical signal 205 has any anomalous variation.

Step 74: If any anomalous variation occurs, the protection device 60 then is notified by the processor 10 to execute the predetermined protection alarm or the protection action.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A piezoelectric generation system, applicable for a nebulizer, the piezoelectric generation system comprising:
a frequency generation unit for continuously generating first electrical signals of a serial predetermined frequency band range based on a serial control signals or a predetermined setting;
a piezoelectric generating element for generating a series of corresponding second electrical signals based on the first electrical signals; and
a processing unit for selectively generating the series of control signals, and controlling the frequency generation unit to provide the first electrical signals with a better frequency to the piezoelectric generating element based on voltage values or feedback frequency values of the series of the second electrical signals and frequency relation of the series of the first electrical signals.

2. The piezoelectric generation system of claim 1, wherein the frequency generation unit transmits the first electrical signals to the piezoelectric generating element.

3. The piezoelectric generation system of claim 1, wherein the processing unit receives the second electrical signals transmitted by the piezoelectric generating element through a feedback signal receiving unit.

4. The piezoelectric generation system of claim 1, wherein serial predetermined frequency band range is predetermined to obtain frequency value of the power of 2, and corresponds to the voltage value of the power of 2 of the series of the second electrical signals or the feedback frequency value respectively.

5. The piezoelectric generation system of claim 4, wherein the first electrical signals with the better frequency is the maximum or minimum voltage value of the power of 2 or the feedback frequency value.

6. The piezoelectric generation system of claim 5, wherein the piezoelectric generation system further comprises a protection unit.

7. The piezoelectric generation system of claim 6, wherein the protection unit determines whether or not a protection alarm or a protection action needs to be activated when the processing unit detects the voltage value or the feedback frequency value of the second electrical signals generated by the piezoelectric generating element.

8. The piezoelectric generation system of claim 7, wherein the protection alarm or the protection action is a display alarm or a buzzer alarm, or is to turn off the power of the nebulizer or a lighting alarm.

9. A piezoelectric generation system, applicable for a nebulzier, the piezoelectric generation system comprising:
a frequency generation unit for receiving a control signal to send first electrical signals with a better frequency;
a piezoelectric generating element for generating corresponding second electrical signal based on the first electrical signals; and
a processing unit for generating the control signal based on a predetermined frequency and voltage or feedback frequency relation table, and detecting whether or not the voltage value or the feedback frequency value of the second electrical signals has anomalous variation, wherein the predetermined frequency and voltage or feedback frequency relation table is predetermined or obtained from the processing unit pre-executing a sweep frequency function.

10. The piezoelectric generation system of claim 9, wherein the frequency generation unit transmits the first electrical signals to the piezoelectric generating element through a signal amplifier unit.

11. The piezoelectric generation system of claim 9, wherein the processing unit receives the second electrical signals transmitted by the piezoelectric generating element through a feedback signal receiving unit.

12. The piezoelectric generation system of claim 9, wherein the predetermined frequency and voltage or feedback frequency relation table is divided into the frequency value of the power of 2, and corresponds to the voltage value of the power of 2 or the feedback frequency value respectively.

13. The piezoelectric generation system of claim 12, wherein the first electrical signal with the better frequency is the maximum or minimum voltage value of the power of 2 or the feedback frequency value.

14. The piezoelectric generation system of claim 9, wherein the piezoelectric generation system further comprises a protection unit.

15. The piezoelectric generation system of claim 14, wherein the protection unit determines whether or not a protection alarm or a protection action needs to be activated based on whether or not the voltage value or the feedback frequency value of the second electrical signals detected by the processing unit has anomalous variation.

16. The piezoelectric generation system of claim 15, wherein the protection alarm or the protection action is a display alarm or a buzzer alarm, or is to turn off the power of the nebulizer or a lighting alarm.

17. A piezoelectric generating method, applicable for a nebulizer, the piezoelectric generating method comprising:
controlling a frequency generation unit or predetermining the frequency generation unit through a processing unit to continuously generate first electrical signals of a serial predetermined frequency band range to a piezoelectric generating element;
enabling the piezoelectric generating element to generate a series of corresponding second electrical signals based on the first electrical signals; and
enabling the processing unit to control the frequency generation unit to provide the first electrical signals with a better frequency for the piezoelectric generating element based on voltage values of the series of the second electrical signals or feedback frequency values and frequency relation of the series of the second electrical signals.

18. The piezoelectric generating method of claim 17, wherein the first electrical signals are further transmitted by a signal amplifier unit to the piezoelectric generating element.

19. The piezoelectric generating method of claim 17, wherein the second electrical signals are further transmitted by a feedback signal receiving unit to the processing unit.

20. The piezoelectric generating method 17, wherein the serial predetermined frequency band range is pre-divided into frequency values of the power of 2, and corresponds to the voltage value of the power of 2 of the series of the second electrical signals or the feedback frequency value respectively.

21. The piezoelectric generating method of claim 20, wherein the first electrical signal with the better frequency is the maximum or minimum voltage value of the power of 2 or the feedback frequency value.

22. The piezoelectric generating method of claim 17, further comprising the step of determining whether or not a protection alarm or a protection action needs to be activated when the processing unit detects the voltage value or the feedback frequency value generated by the piezoelectric generating element.

23. The piezoelectric generating method of claim 22, wherein the protection alarm or the protection action is a display alarm or a buzzer alarm, or is to turn off the power of the nebulizer or a lighting alarm.

24. A piezoelectric generating method, applicable for a nebulizer, the piezoelectric generating method comprising:
receiving a control signal through a frequency generation unit, and sending first electrical signals with a better frequency;
transmitting the first electrical signals to a piezoelectric generating element to generate a corresponding second electrical signal; and
sending a control signal from a processing unit based on a predetermined frequency and voltage or feedback frequency relation table, and detecting whether or not the voltage value or the feedback frequency value of the second electrical signals has anomalous variation, wherein the predetermined frequency and voltage or feedback frequency table is predetermined or obtained from the processing unit pre-executing a sweep frequency function.

25. The piezoelectric generating method of claim 24, wherein the first electrical signals are transmitted by a signal amplifier unit to the piezoelectric generating element.

26. The piezoelectric generating method of claim 24, wherein the second electrical signals are transmitted by a feedback signal receiving unit to the processing unit.

27. The piezoelectric generating method of claim 24, wherein the predetermined frequency and voltage or feedback frequency table is divided into frequency values of the power of 2, and corresponds to the voltage value of the power of 2 or the feedback frequency value respectively.

28. The piezoelectric generating method of claim 27, wherein the first electrical signal with the better frequency corresponds to the maximum or minimum voltage value of the power of 2 or the feedback frequency value.

29. The piezoelectric generating method of claim 24, further comprising the step of determining whether or not a protection alarm or a protection action needs to be activated based on whether or not the voltage value or the feedback frequency value of the second electrical signal detected by the processing unit has anomalous variation.

30. The piezoelectric generating method of claim 29, wherein the protection alarm or the protection action is a display alarm or a buzzer alarm, or is to turn off the power of the nebulizer or a lighting alarm.
